(19) United States
(12) Patent Application Publication
(10) Pub. No.: US 2005/0133816 A1
(43) Pub. Date: Jun. 23, 2005

(54) III-nitride quantum-well field effect transistors

(76) Inventors: Zhaoyang Fan, Manhattan, KS (US); Jing Li, Manhattan, KS (US); Hongxing Jiang, Manhattan, KS (US); Jingyu Lin, Manhattan, KS (US)

Correspondence Address: CHASE LAW FIRM L.C, 4400 COLLEGE BOULEVARD, SUITE 130, OVERLAND PARK, KS, 66211, US

(21) Appl. No.: 10/741,268

(22) Filed: Dec. 19, 2003

(51) Int. Cl. H01L 31/072

(52) U.S. Cl. 257/190

(57) ABSTRACT

A transistor with improved device characteristics includes a substrate, a first buffer layer deposited on the substrate, a highly resistive epilayer deposited on the buffer layer, a second epilayer deposited on the highly resistive epilayer, a channel layer deposited on the second epilayer, an AlGaN alloy epilayer deposited on the channel layer, and source, gate, and drain connections deposited on the AlGaN alloy epilayer. The highly resistive epilayer may include AlGaN, InAlGaN, AlBN, or AlN compositions. The channel layer may include InGaN, graded InGaN, multilayers of InGaN and GaN, or GaN.

### BACKGROUND OF THE INVENTION

1. Field of the Invention

The present invention relates to a semiconductor device having improved device characteristics and, in particular, to a field effect transistor constructed of the AlGaN/GaN/AlN(AlGaN) quantum-well heterostructure with improved (i) amplification characteristics, (ii) power and frequency performances, and (iii) reliability and stability.

2. Description of the Prior Art

Modern microelectronic devices based on semiconductor heterojunction field-effect transistors (HFETs), also called high electron mobility transistors (HEMTs) or modulation doped field effect transistor (MODFET), have a wide range of applications, including communications such as radar links, direct broadcast satellite television, cellular telephone, cable television converters, and data processing applications. These III-V compound semiconductor HFET, HEMT or MODFET devices use the high mobility property of the two-dimensional (2-D) electron gas formed at the hetero-interface of two different semiconductors to achieve a high performance for the devices. The HFET devices fabricated by more conventional technologies (e.g., AlGaAs) have been in production for many years. However, the military and modern microelectronic industries are constantly faced with demands for higher device performance. Power amplifiers are the major factor in performance and cost for next-generation base stations. In amplifying high-frequency RF signals, most of the power consumed is lost to heat. This heat results in reduced reliability of these devices and systems and higher air-conditioning costs, contributing to substantially larger and more expensive base stations. There is an urgent need to develop high-performance electronic building blocks that combine lower costs with improved performance and manufacturability. Of the contenders, III-nitrides are emerging as the most promising materials. The HFET devices using the III-nitride compound semiconductors (AlGaN/GaN on buffer and substrate) have the potential to achieve outstanding operational characteristics because of their unique combination of material characteristics, such as wide bandgap, high breakdown field, strong polarization effect, and high saturation electron velocity. Due to their intrinsic robust physical properties, III-nitride based electronic devices may operate at higher temperatures, voltages, and power levels, and in harsher environments than other semiconductor devices, and are expected to provide much lower temperature sensitivity, which are crucial advantages for many commercial and military applications.

The conventional III-nitride semiconductor heterostructure FET (HFET, HEMT, or MODFET) has been described by Khan (U.S. Pat. No. 5,192,987), Khan et al., “Hall measurements and contact resistance in doped GaN/AlGaN heterostructure,” Applied Physics Letter, Vol. 68, May 1996, Page 3022; and Ping et al., “DC and microwave performance of high current AlGaN heterostructure field effect transistors grown on p-type SiC substrate,” IEEE Electron Device Letters, Vol. 19, No. 2, February 1998, Page 54. The conventional AlGaN/GaN HFET structure (of prior art) is generally formed by a single heterostructure of AlGaN and GaN, as shown in FIG. 1 and indicated by reference numeral 100. It includes the substrate 102, the thin low temperature grown buffer 104 (GaN or AlN), a relatively thick semi-insulating GaN epilayer 106 (a few microns), and the AlGaN barrier layer 108. The device has source 110 (S), drain 112 (D), and gate 114 (G) contacts. The 2-D electron gas formed at the interface of the GaN epilayer 106 and the AlGaN barrier layer 108 is indicated by reference numeral 116. Some of the devices have shown very promising results. As an example, Shealy et al. have reported a radio-frequency (RF) power density for small-periphery devices of more than 11 W/mm at 10 Ghz (“An AlGaN/GaN high-electron-mobility transistor with an AlN sub-buffer layer,” Journal of Physics: Condensed Matter, Vol. 14, No. 13, May 2002, page 3499).

Although AlGaN/GaN HFETs have reached a high performance level, they still suffer from many problems, such as drain current collapse phenomenon. Many of the problems are caused by parasitic conduction in the semi-insulating GaN epilayer, the spillover of channel electrons into the semi-insulating GaN epilayer, and charge trapping by the defects in the semi-insulating GaN epilayer. The drain current collapse phenomenon under RF operation limits the output microwave power and instability of the device. The GaN epilayer 106 must be highly resistive in order to minimize these problems and to ensure the device working properly.

In reality, it is difficult to grow highly resistive GaN. Accordingly, the resistance of the GaN epilayer is too low (due to the presence of unintentional impurities and defects), which introduces a parasitic current and degrades device performance. In the worst case, the transistor cannot be pinched off. Although growth at low pressure by introducing more defects or anti-doping by carbon or iron may be used to increase the GaN resistivity, the dopants have been shown to increase the defect density in the GaN bulk epilayer and enhance the current collapse phenomenon.

Additionally, for conventional HFETs grown on SiC or Si, semi-insulating SiC or Si substrate loses their semi-insulating properties at above 400° C., which leads to very high leakage currents at high temperatures.

A need remains in the art for III-nitride HFETs with improved performance characteristics.

### BRIEF SUMMARY OF THE INVENTION

The present invention provides an improved III-nitride quantum-well based field effect transistor (QW-FET) structure/device. The substrate may be Sapphire, Silicon, Silicon Carbide, or other appropriate materials. On the top of this substrate, a highly resistive thick epilayer such as Aluminum Nitride (AlN), Aluminum Gallium Nitride (AlGaN), Indium Aluminum Gallium Nitride (InAlGaN), or Aluminum Boron Nitride (AlBN), for example, is first deposited on a low temperature grown buffer layer as the epitaxial template for the subsequent layers. The low temperature buffer layer may include AIN, AlGaN, InAlGaN, AlBN, or GaN. AlN (or AlGaN, InAlGaN, AlBN) alloy epilayer is then grown as the bottom barrier and insulating layer, followed by a thin channel layer such as GaN, Indium Gallium Nitride (InGaN), graded InGaN or multilayers of InGaN and GaN, for example with a thickness from tens of nanometers to hundreds of nanometers. The last AlGaN alloy epilayer as the top barrier finishes the whole structure. Because the low bandgap GaN channel layer is sandwiched between the bottom high bandgap AIN (AlGaN) layer and the top high bandgap AlGaN layer, the device structure is a quantum-well. The device has source, drain, and gate contacts.

### BRIEF DESCRIPTION OF THE SEVERAL VIEWS OF THE DRAWINGS

FIG. 1 is a fragmentary cross sectional view of a conventional heterostructure filed effect transistor (HFET) structure based on an AlGaN/GaN heterojunction.

FIG. 2 is a fragmentary cross sectional view of the quantum-well field effect transistor (QW-FET) structure based on AlGaN/GaN/AlN (AlGaN) of the present invention.

FIG. 3 is a diagram illustrative of the band diagram for an Al_{0.3}Ga_{0.7}N/GaN (50 nm)/AlN QW-FET structure.

FIG. 4 is a diagram illustrative of two dimensional electron distributions at AlGaN/GaN heterojunction for delta doping and uniform doping with the same amount of dopants.

FIG. 5 is a diagram illustrative of the relationship between the simulated 2-D electron densities and the GaN channel thickness for different Al contents in the top AlGaN barrier with delta doping.

FIG. 6 is a diagram illustrative of the simulated conduction band edge of Al_{0.3}Ga_{0.7}N/GaN/AlN QW-FET structure with backside doping.

FIG. 7 is a diagram illustrative of the comparison of electron distribution with and without backside doping.

FIG. 8 is a diagram illustrative of the on-wafer drain-source DC current-voltage characteristics of an Al_{0.3}Ga_{0.7}N/GaN/AlN QW-FET of the present invention.

FIG. 9 is a diagram illustrative of the gate lag measurement result of an Al_{0.3}Ga_{0.7}N/GaN/AlN QW-FET of the present invention with gate pulsing from −10V (deep pinch off) to 0V.

### DETAILED DESCRIPTION OF THE INVENTION

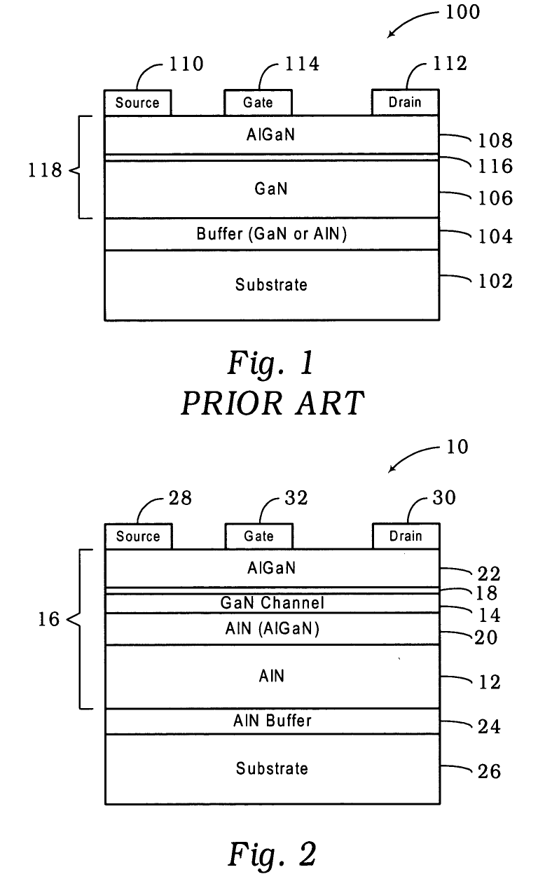

Comparing the conventional AlGaN/GaN HFET structure of the prior art illustrated in FIG. 1 with the present invention illustrated in FIG. 2, the novel QW-FET structure of this invention generally identified by reference numeral 10 incorporates several distinctive schemes. The first three include: (1) replacing the “semi-insulating” GaN epilayer 106 with a highly resistive epilayer 12, (2) employing only a thin channel layer 14 (a few tens of nanometers to a few hundreds of nanometers) instead of a thick GaN epilayer 106 (a few microns) as the channel layer, and consequently (3) substituting the conventional AlGaN/GaN single heterostructure 118 with the AlGaN/GaN/AIN(AlGaN) quantum-well structure 16. By doing so, the parasitic conduction in the thick GaN epilayer 106 and leakage current of the prior art will be completely eliminated and the drain current collapse will be reduced, and hence the amplification characteristics will be improved. Moreover, the reduction of the channel layer 14 thickness may also improve the device's speed and frequency response.

Highly resistive layer 12 may include AlGaN, InAlGaN, AlBN, or AlN, for example. Each of these compositions are highly resistive. The thin channel layer 14 may include GaN, InGaN, graded InGaN, or multilayers including InGaN and GaN, for example.

For the AlGaN/GaN/AlN(AlGaN) QW-FET structure, one may also incorporate new schemes to increase the channel electron density, generally indicated by reference numeral 18, because the negative polarization charge at the bottom channel layer 14 and AlN(AlGaN) layer 20 interface could possibly deplete the 2-D electron gas density 18. To increase the 2-D electron density 18, an n-type delta-doping scheme in the top AlGaN barrier layer 22 is used along with doping the backside of the channel layer 14 so the dopants are away from the top interface between channel layer 14 and AlGaN layer 22.

For conventional HFETs grown on SiC or Si, semi-insulating SiC or Si substrate 102 loses their semi-insulating properties at above 400° C., which leads to very high leakage currents at high temperatures. By depositing a highly resistive epilayer 12 before preparing the active transistor layers, the active layers will be completely electrically isolated from the semi-insulating substrate 26, which in turn will greatly improve the power and frequency performances at high temperatures for HFET devices grown on semi-insulating substrates.

For more details of QW-FET structure 10 (FIG. 2) of this invention, the top AlGaN barrier layer 22 may be unintentionally doped or intentionally doped, and the dopants may be uniformly distributed in the entire layer or concentrated into an extremely thin layer within the layer (called delta-doping). Between the AlGaN barrier layer 22 and the channel layer 14, a very thin layer of AlN (˜1 nm) may also be deposited to reduce the interface alloy scattering. The channel layer 14 may be undoped or intentionally doped, and in particular, the lower part of this layer may be intentionally doped (backside doping). The backside doping overcomes the problem of the negative polarization bounded charge at the interface of channel layer 14 and layer 20 and increases the 2-D electron density without sacrificing its mobility. Layer 20 may be AlN or AlGaN (or InAlGaN) alloy with different aluminum contents. Layer 12 may incorporate a buffer layer 24 at the bottom side.

The QW-FET structure 16 of the present invention comprises two barrier layers. The thin GaN channel layer 14 is sandwiched by the top AlGaN barrier layer 22 and the bottom AlN (or AlGaN or InAlGaN) barrier layer 20. In the conventional HFET structure 118, there is only one AlGaN barrier layer 108 on the top, and the bottom thick GaN bulk epilayer 106. With the highly resistive epilayer 12 of AlN, AlGaN, InAlGaN, or AlBN, for example, replacing the semi-insulating GaN thick epilayer 106, the parasitic conduction in the GaN bulk 106 is completely removed and leakage current is reduced. The AlN or AlGaN or InAlGaN (with high Al composition) layer 20 has a much wider bandgap than channel layer 14, and this large conduction band offset between the channel 14 and AlN (or AlGaN) epilayer 20 limits the spill-over of channel electrons into the bulk epilayer, thereby minimizing the drain current collapse due to defects trapping in GaN epilayer 106, and improving the device amplification characteristics.

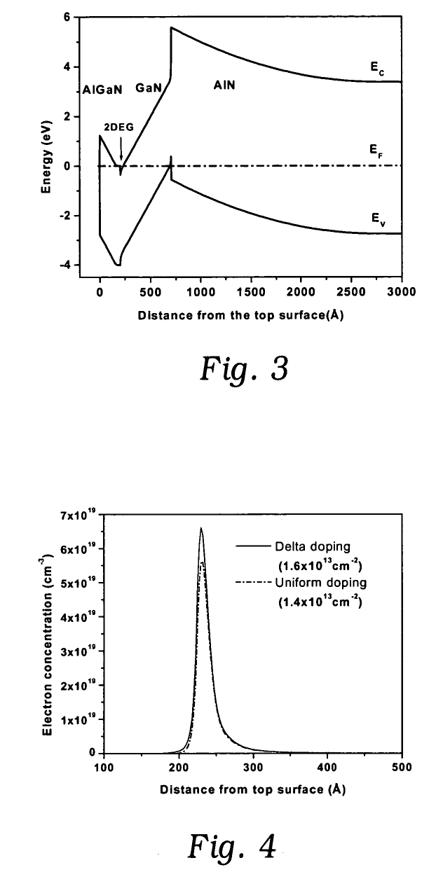

In general, the output power of the III-nitride HFET devices 100 depends on the 2-D electron density 116 in the channel. For the AlGaN/GaN/AlN(AlGaN) QW-FET device 10 of the present invention, one would also incorporate new techniques to enhance the channel electron density because the negative polarization charge at the bottom interface between channel layer 14 and AlN(AlGaN) layer 20 could decrease the 2-D electron gas 18 (which is enhanced by this same polarization effect at the top interface between AlGaN layer 22 and channel layer 14). The conduction band and the electron distribution of the AlGaN/GaN/AlN quantum well may be determined by solving Poisson equation and Schrödinger equation self-consistently using existing educational software developed by Notre Dame University that has been used successfully by several groups for HFET structural design. The calculated band diagram and the electron distribution for an Al_{0.3}Ga_{0.7}N/GaN(50 nm)/AlN QW-FET structure are shown in FIG. 3. Here the channel layer of GaN has a thickness of 50 nm and is treated as fully relaxed. Only spontaneous polarization charges appear at the GaN/AlN (AlGaN) interface. The negative bounded charge at the GaN/AlN(AlGaN) interface may decrease the electrons in the GaN channel by lifting up the conduction band edge. Compared to the conventional AlGaN/GaN HFET structure (FIG. 1), the 2-D electron density (nₛ) in an Al_{0.3}Ga_{0.7}N/GaN(50 nm)/AlN QW-FET structure (FIG. 2) could decrease by more than 30% without incorporating other methods to minimize the influence of the negative polarization charge at the bottom interface between GaN channel layer 14 and AlN layer 20 and to enhance the 2-D electron density 18 in the channel.

In order to take the advantage of high resistivity of the AlN epitaxial template, and at the same time without sacrificing the high 2-D electron density (nₛ), the present invention also provides methods to overcome the charge depletion effect (or negative bounded polarization charge problem). These methods can also be combined together. The effect of the negative polarization charge between the GaN and AlN (AlGaN) interface on the 2-D channel electron density can be minimized by optimizing the structure and adoption of several techniques, as discussed hereinbelow.

One such technique is using the n-type delta-doping scheme in the top AlGaN barrier layer 22. In the conventional HFET structure 100, the top AlGaN barrier layer 108 is uniformly doped. The QW-FET structure 10 of the present invention substitutes this uniform doping with a delta doping. Referring to FIG. 4, calculation results demonstrate that the delta doping scheme gives a higher 2-D electron density than that of uniformly doping with a 14% increase. This enhancement is due to the fact that uniformly distributed dopant ions will screen the polarization field, while delta doping does not.

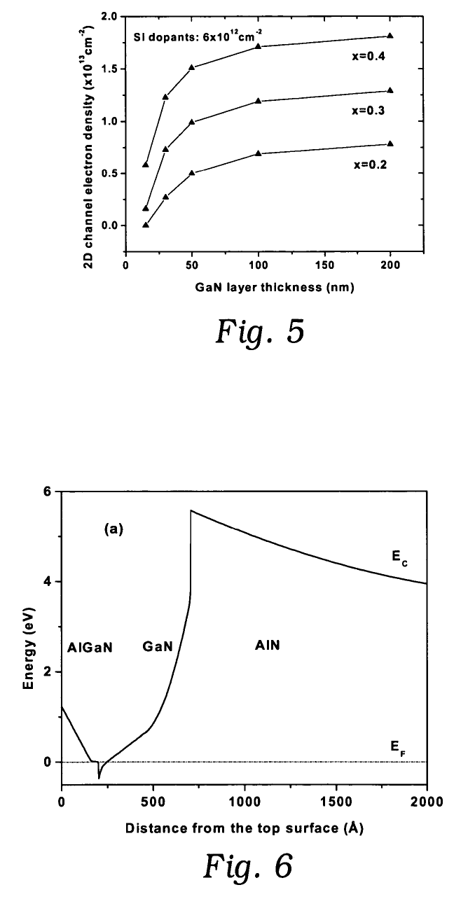

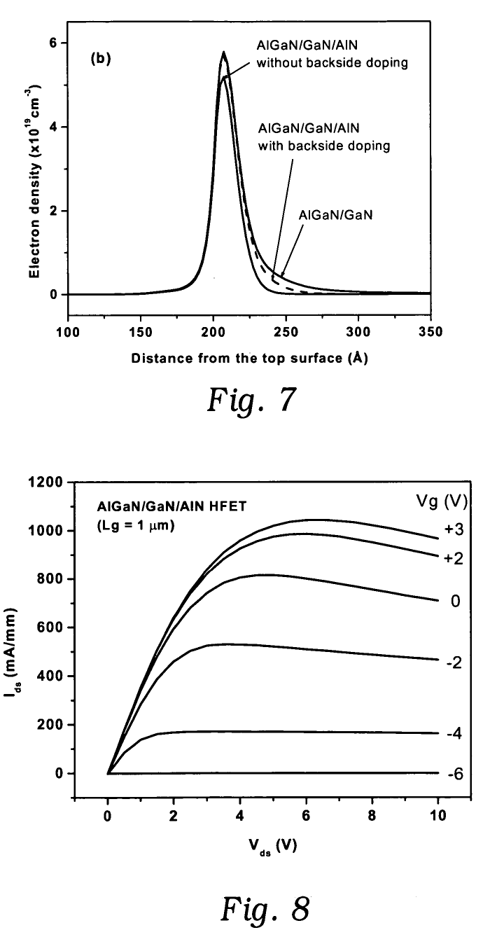

The second method for reducing the depletion effect of the negative polarization charge at the GaN/AlN(AlGaN) interface is to increase the Al content in the AlGaN top barrier 22. FIG. 5 shows the relationship between the simulated 2-D electron densities 18 and the GaN channel 14 thickness for different Al contents in the top AlGaN barrier layer 22, which illustrates that a higher Al content in the top AlGaN barrier provides higher 2-D electron densities 18. 281 The third method to achieve a high 2-D electron density is backside doping in the channel layer. As illustrated in FIG. 3, the polarization charges at the interface between the channel layer 14 of GaN and AlN(AlGaN) layer 20 lift up the band edge of the channel layer 14 and introduce a built-in electrical field, pointing to the 2-D channel 18 at the interface between AlGaN layer 22 and the channel layer 14. If the bottom side of the channel layer 14 is doped, the introduced electrons will accumulate in the 2-D channel 18 naturally, separating from the dopant atoms by the electric field. FIGS. 6 and 7 show the simulated conduction band edge and electron distribution for one case of backside doping for an Al_{0.3}Ga_{0.7}N/GaN(50 nm)/AlN QW-FET structure. Here for the total 50 nm thick GaN channel layer, the bottom 25 nm is doped by silicon. The electrons introduced by backside doping accumulate in the 2-D channel, and the sheet carrier density increases to a level (1.4×10¹³ cm⁻²), which is comparable to the value in a conventional AlGaN/GaN single heterostructure FET. It should be understood that the backside doping in the present invention is different from the channel doping in the convention HFET structure. In the later case, the dopants reduce the mobility of the channel electrons and decrease the device performance. In the present invention the backside doping in the electrical field inherently separates the dopants from the electrons avoiding a reduction in the mobility of channel electrons and device performance.

A graded AlGaN layer 20 may also be introduced between highly resistive epilayer 12 and channel layer 14 by gradually reducing the aluminum composition of the graded layer. The introduction of this graded layer reduces the polarization effect hence minimize the influence on the 2-D electron density.

To verify the abovementioned concepts, Al_{0.3}Ga_{0.7}N/GaN/AlN(AlGaN) QW-FET structures were grown by MOCVD. By combining the graded AlGaN layer 20, the backside doping in the GaN channel layer 14, and delta doping in the AlGaN barrier layer 22 into Al_{0.3}Ga_{0.7}N/GaN(50 nm)/AlN(AlGaN) QW-FET structures of the present invention, the structures exhibit 2-D electron density values as high as 1.8×10¹³ cm⁻².

To demonstrate the advantageous features of AlGaN/GaN/AlN QW-FET of this invention, devices were fabricated from Al_{0.3}Ga_{0.7}N/GaN/AlN quantum well wafers that incorporate all the methods described herein by photolithography patterning together with plasma dry etching and contact metallization. On-wafer measured drain-source DC current-voltage characteristics for one such device is shown in FIG. 8.

Referring to FIG. 8, devices with a gate length of ˜1 μm, a source-drain distance of 3 μm and a gate width of 80 μm have been fabricated. The drain current has a maximum value of more than 1 A/mm and the device is completely pinched off at a gate bias of −6 V. For structures grown on sapphire, these are the best results ever achieved for nitride HFETs. These results demonstrate the advantages of AlGaN/GaN/AlN QW-FETs of the present invention. Even without special passivation processing, the device exhibits only a minor drain current collapse under pulse gate driving.

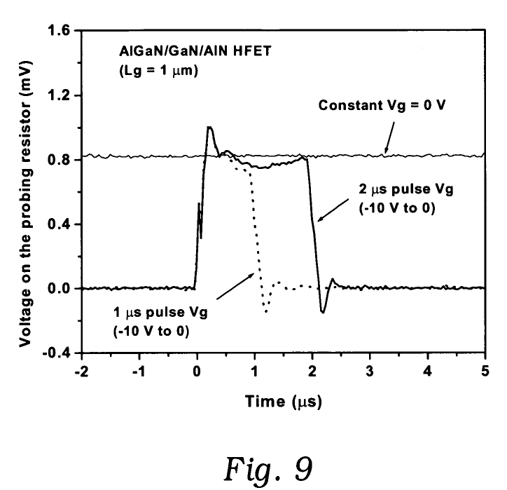

Referring to FIG. 9, the gate lag measurement of an Al_{0.3}Ga_{0.7}N/GaN/AlN QW-FET with gate pulsing from −10V (deep pinch off) to 0V is illustrated. For this measurement, a small resistor is connected in series with the QW-FET device, and a digital oscilloscope is used to measure the voltage on this probing resistor, which is proportional to the drain current. The drain current only has a small reduction (<10%) under 1 μs gate pulse driving, a dramatic improvement over conventional AlGaN/GaN devices, which generally have a 30%-50% reduction under pulse driving. This result is also comparable with the best passivated devices ever reported, which shows the drain current of the Sc₂O₃ passivated Sc₂O₃/AlGaN/GaN device has a decrease of less than 10% in the gate lag measurement. After passivation the devices of the present invention may have even higher performance.

A potential extent application of this invention is related with the low resistive substrates. For RF devices, the substrates must have a high resistance to avoid the power consumption caused by the parasitic current in the substrates. The low conductivity of the substrates also decreases the frequency response of the devices. Although silicon (Si) and silicon carbide (SiC) substrates are better than the current widely used sapphire for the nitride HFET devices, it is difficult and expensive to achieve highly resistive Si and SiC substrates.

The structure of this invention may be extended to use low resistive substrates, since AlN epitaxial templates are highly resistive. By depositing a highly resistive epilayer before preparing the active transistor layers, the active layers will be completely electrically isolated from the low resistive substrate, making the use of low resistive substrates for III-nitride FETs possible. The technique of backside doping may also be extended to the GaN FET devices with AlN (AlGaN) epilayer on other substrates.

Compared to a very recent publication reporting the AlGaN/GaN HFET structure homoepitaxially grown on bulk AlN substrate, where the use of AlN bulk was intended to reduce the number of growth defects and dislocation density, the new methods described in this invention provide AlGaN/GaN/AlN QW-FET with a much higher performance. Moreover, the recently reported AlGaN/GaN HFET structures are specifically grown homoepitaxially on AlN bulk substrates, which are still very small and expensive, while the present AlGaN/GaN/AlN QW-FET structure can be deposited on foreign substrates of varying resistivities.

It is to be understood that while certain forms of this invention have been illustrated and described, it is not limited thereto, except in so far as such limitations are included in the following claims and allowable equivalents thereof.

1. A transistor comprising:
a substrate;
a first buffer layer deposited on said substrate;
a first epilayer deposited on said buffer layer;
a second epilayer deposited on said first epilayer;
a GaN channel layer deposited on said second epilayer;
an AlGaN alloy epilayer deposited on said GaN channel layer;
a plurality of electrical connections deposited on said AlGaN alloy epilayer comprising:
a source connection, a gate connection and a drain connection thereby permitting a difference of electrical potential to be applied to said AlGaN alloy layer so as to permit operation as a transistor.

2. The transistor as set forth in claim 1 wherein said substrate is an insulating or semi-insulate substrate.

3. The transistor as set forth in claim 1 wherein said first epilayer comprises a highly resistive aluminum nitride (AlN) layer.

4. The transistor as set forth in claim 1 wherein said second epilayer comprises an aluminum nitride layer.

5. The transistor as set forth in claim 1 wherein said second epilayer comprises an aluminum gallium nitride layer.

6. The transistor as set forth in claim 1 wherein said GaN channel layer is generally less than 500 nanometers thick.

7. The transistor as set forth in claim 1 wherein said AlGaN alloy epilayer includes an n-type delta-doping.

8. The transistor as set forth in claim 1 wherein said AlGaN alloy epilayer includes an n-type doping.

9. The transistor as set forth in claim 1 wherein said GaN channel layer is backside doped.

10. The transistor as set forth in claim 1 further comprising a thin layer of AlN deposited between said GaN channel layer and said top AlGaN layer.

11. The transistor as set forth in claim 1 wherein said GaN channel layer is undoped.

12. The transistor as set forth in claim 1 wherein said GaN channel layer is intentionally doped.

13. The transistor as set forth in claim 1 wherein said the second epilayer has a graded aluminum composition.

14. A transistor comprising:
an insulating or semi-insulating substrate;
a first buffer layer deposited on said substrate;
a highly resistive aluminum nitride (AlN) epilayer deposited on said buffer layer;
an aluminum gallium nitride epilayer deposited on said highly resistive aluminum nitride (AlN) epilayer;
a GaN channel layer deposited on said aluminum gallium nitride epilayer;
an AlGaN alloy epilayer deposited on said GaN channel layer;
a plurality of electrical connections deposited on said AlGaN alloy epilayer comprising:
a source connection, a gate connection and a drain connection thereby permitting a difference of electrical potential to be applied to said AlGaN alloy layer so as to permit operation as a transistor.

15. The transistor as set forth in claim 14 wherein said GaN channel layer is generally less than 500 nanometers thick.

16. The transistor as set forth in claim 14 wherein said AlGaN alloy epilayer includes an n-type delta-doping.

17. The transistor as set forth in claim 14 wherein said AlGaN alloy epilayer includes an n-type doping.

18. The transistor as set forth in claim 14 wherein said GaN channel layer is backside doped.

19. The transistor as set forth in claim 14 further comprising a thin layer of AlN deposited between said GaN channel layer and said top AlGaN layer.

20. The transistor as set forth in claim 14 wherein said GaN channel layer is undoped.

21. The transistor as set forth in claim 14 wherein said GaN channel layer is intentionally doped.

22. The transistor as set forth in claim 14 wherein said aluminum gallium nitride epilayer has a graded aluminum composition.

23. A transistor comprising:
an insulating or semi-insulating substrate;
a first buffer layer deposited on said substrate;
a highly resistive aluminum nitride (AlN) epilayer deposited on said buffer layer;
an aluminum gallium nitride epilayer deposited on said highly resistive aluminum nitride (AlN) epilayer;
a backside doped GaN channel layer deposited on said aluminum gallium nitride epilayer;
an n-type doped AlGaN alloy epilayer deposited on said GaN channel layer;
a plurality of electrical connections deposited on said AlGaN alloy epilayer comprising:
a source connection, a gate connection and a drain connection thereby permitting a difference of electrical potential to be applied to said AlGaN alloy layer so as to permit operation as a transistor.

24. The transistor as set forth in claim 23 wherein said backside doped GaN channel layer is generally less than 500 nanometers thick.

25. The transistor as set forth in claim 23 wherein said n-type doped AlGaN alloy epilayer includes an n-type delta-doping.

26. The transistor as set forth in claim 23 further comprising a thin layer of AlN deposited between said backside doped GaN channel layer and said top AlGaN layer.

27. The transistor as set forth in claim 23 wherein said aluminum gallium nitride epilayer has a graded aluminum composition.

28. A transistor comprising:
a substrate;
a first buffer layer deposited on said substrate;
a first epilayer deposited on said buffer layer;
a second epilayer deposited on said first epilayer;
a channel layer deposited on said second epilayer;
an AlGaN alloy epilayer deposited on said channel layer;
a plurality of electrical connections deposited on said AlGaN alloy epilayer comprising:
a source connection, a gate connection and a drain connection thereby permitting a difference of electrical potential to be applied to said AlGaN alloy layer so as to permit operation as a transistor.

29. The transistor as set forth in claim 28 wherein said substrate is an insulating or semi-insulating substrate.

30. The transistor as set forth in claim 28 wherein said first epilayer comprises a highly resistive aluminum nitride (AlN) layer.

31. The transistor as set forth in claim 28 wherein said first epilayer comprises a highly resistive aluminum gallium nitride (AlGaN) layer.

32. The transistor as set forth in claim 28 wherein said first epilayer comprises a highly resistive indium aluminum gallium nitride (InAlGaN) layer.

33. The transistor as set forth in claim 28 wherein said first epilayer comprises a highly resistive aluminum boron nitride (AlBN) layer.

34. The transistor as set forth in claim 28 wherein said second epilayer comprises an aluminum nitride (AlN) layer.

35. The transistor as set forth in claim 28 wherein said second epilayer comprises an aluminum gallium nitride (AlGaN) layer.

36. The transistor as set forth in claim 28 wherein said second epilayer comprises an indium aluminum gallium nitride (InAlGaN) layer.

37. The transistor as set forth in claim 28 wherein said channel layer comprises a gallium nitride (GaN) layer.

38. The transistor as set forth in claim 28 wherein said channel layer comprises an indium gallium nitride (InGaN) layer.

39. The transistor as set forth in claim 28 wherein said channel layer comprises a graded indium gallium nitride (InGaN) layer.

40. The transistor as set forth in claim 28 wherein said channel layer comprises an indium gallium nitride (InGaN) layer and a gallium nitride (GaN) layer.

41. The transistor as set forth in claim 28 wherein said channel layer is generally less than 500 nanometers thick.

42. The transistor as set forth in claim 28 wherein said AlGaN alloy epilayer includes an n-type delta-doping.

43. The transistor as set forth in claim 28 wherein said AlGaN alloy epilayer includes an n-type doping.

44. The transistor as set forth in claim 28 wherein said channel layer is backside doped.

45. The transistor as set forth in claim 28 further comprising a thin layer of AlN deposited between said channel layer and said top AlGaN layer.

46. The transistor as set forth in claim 28 wherein said channel layer is undoped.

47. The transistor as set forth in claim 28 wherein said channel layer is intentionally doped.

48. The transistor as set forth in claim 28 wherein said the second epilayer has a graded aluminum composition.
